(19) United States
(12) Patent Application Publication
(10) Pub. No.: US 2026/0188407 A1
(43) Pub. Date: Jul. 2, 2026

(54) NEW TECHNICAL TO ADJUST BFEA DYNAMICALLY

(71) Applicant: Micron Technology, Inc., Boise, ID (US)

(72) Inventors: Deping He, Boise, ID (US); Bo Zhou, Shanghai (CN); Jiao Xiong, Shanghai (CN)

(21) Appl. No.: 19/420,461

(22) Filed: Dec. 15, 2025

Related U.S. Application Data
(60) Provisional application No. 63/739,059, filed on Dec. 26, 2024.

(51) Int. Cl. G11C 29/12

(52) U.S. Cl. CPC G11C 29/12005

(57) ABSTRACT

Methods, systems, and devices for dynamic adjustment of bin offsets are described. A memory system may perform a dynamic bin offset adjustment procedure, in which bin offsets configured for read voltage adjustment at the memory system may be adjusted according to performance results of test read operations. For example, the memory system may perform one or more read operations, which may be utilized to adjust each bin offset, for example, by increasing or decreasing the bin offsets over multiple repetitions or over a life cycle of the memory system. The memory system may obtain measurements in response to the one or more read operations to determine whether such adjustments increase read performance and may apply the adjustments to the bin offset values stored at the memory system accordingly.

### CROSS REFERENCE

The present application for patent claims priority to U.S. Patent Application No. 63/739,059 by He et al., entitled “DYNAMIC ADJUSTMENT OF BIN OFFSETS,” filed Dec. 26, 2024, which is assigned to the assignee hereof, and which is expressly incorporated by reference in its entirety herein.

### TECHNICAL FIELD

The following relates to one or more systems for memory, including dynamic adjustment of bin offsets.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not- or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports dynamic adjustment of bin offsets in accordance with examples as disclosed herein.

FIG. 2 shows an example of a process that supports dynamic adjustment of bin offsets in accordance with examples as disclosed herein.

FIG. 3 shows a block diagram of a memory system that supports dynamic adjustment of bin offsets in accordance with examples as disclosed herein.

FIG. 4 shows a flowchart illustrating a method or methods that support dynamic adjustment of bin offsets in accordance with examples as disclosed herein.

### DETAILED DESCRIPTION

Some memory systems may perform a scan operation (e.g., a block family scan, a block family error avoidance (BFEA) scan) to track charge loss of memory cells across multiple blocks of the memory system and assign each block of the multiple blocks to a respective bin of a set of bins according to the measured charge loss. For example, each bin of a memory system may define a grouping of blocks that have a similar elapsed time since programming (e.g., were programmed at or around the same time). Accordingly, each block within a bin may have or correspond to a similar amount of charge loss.

In such examples, each bin may be associated with multiple bin offsets (e.g., read voltage offsets), where each bin offset may be associated with a respective voltage level that may be programmed into a memory cell. The memory system may utilize the bin offsets during read operations to account for the charge loss and resulting voltage distribution, thereby reducing a quantity of errors read from respective blocks. For example, the memory system may perform a first read operation on a first block by applying a first read voltage to the first block, where the first read voltage may be based on (e.g., adjusted according to) a base read voltage level (e.g., a standard read voltage) and a first bin offset (e.g., a default bin offset). In such examples, the first bin offset may be associated with a first read voltage level programmed into one or more memory cells of the first block.

In some cases, the values of the bin offsets may be configured at the memory system. For example, the bin offsets may be collected during a scanning operation performed during a manufacturing process associated with the memory system or during power on (or some combination thereof), and the bin offsets may fail to reflect a current condition of the memory system (e.g., may be based on outdated information or measurements). Additionally, or alternatively, the bin offsets may be applied uniformly across memory devices of the memory system, without consideration for unit-to-unit charge loss variations which may occur. According to these and other examples, the memory system may perform reads with read voltages that are inaccurate (due to the preconfigured or static bin offsets), which may result in errors in memory access and increased latencies.

In accordance with examples described herein, the memory system may perform a dynamic bin offset adjustment procedure, in which the bin offsets at the memory system may be adjusted according to performance metrics obtained based on (e.g., in response to) one or more read operations. That is, the memory system may iteratively adjust (e.g., increase and/or decrease) the bin offsets over multiple repetitions or over a life cycle of the memory system. For example, based on (e.g., in response to) performing one or more scan operations to assign multiple blocks of a memory system to a respective bin, the memory system may perform one or more read operations on a first set of blocks associated with a first bin, where the one or more read operations may be associated with a first voltage level (and associated with a first bin offset of the first bin). Accordingly, the memory system may determine a quantity of blocks having a respective performance metric that satisfies a performance threshold according to performing the one or more read operations. The memory system may use the determined quantity of blocks to adjust (e.g., increment, decrement) the first bin offset or maintain the first bin offset. By performing the adjustment of the first bin offset in response to the scan operation, the memory system may maintain up-to-date bin offsets (e.g., accurate bin offsets), thereby ensuring the accuracy of future read operations, reducing errors during the read operations, and/or reducing latency during the read operations, among other examples.

In addition to applicability in memory systems as described herein, techniques for dynamic adjustment of bin offsets may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

Features of the disclosure are illustrated and described in the context of systems, devices, and circuits. Features of the disclosure are further illustrated and described in the context of processes, and flowcharts.

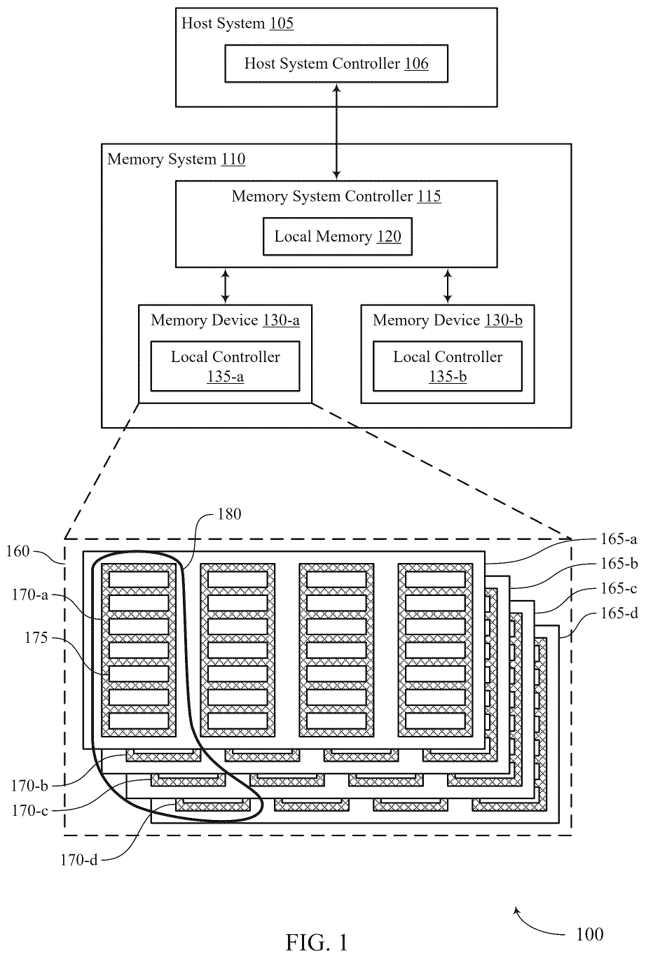

FIG. 1 shows an example of a system 100 that supports dynamic adjustment of bin offsets in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

Some memory systems 110 may perform a scan operation (e.g., a block family scan, a block family error avoidance (BFEA) scan) to track charge loss of memory cells across multiple blocks 170 of the memory system 110 and assign each block 170 to a respective bin of a set of bins according to the measured charge loss. As described herein, each bin may define a grouping of blocks 170 that have a substantially similar elapsed time since programming (e.g., are programmed at or around the same time). Accordingly, each block 170 within a bin may have a similar amount of charge loss, where an amount of charge loss of a block 170 may be a function of the elapsed time from a programming operation, a temperature fluctuation of the memory system 110, or both. Each bin may be associated with multiple bin offsets, where each bin offset may be associated with a respective voltage level that may be programmed into a memory cell.

According to the bins assigned to each block 170 of the multiple blocks 170, the memory system may determine offsets to base read voltages that a memory device 130 applies to one or more read operations. For example, a memory system 110 (e.g., a memory system controller 115) may perform read operations by applying one or more read voltages to blocks 170 of memory cells, and each of the read voltages used may be based on (e.g., adjusted according to) a base read voltage level (e.g., a standard read voltage) and a bin offset (e.g., a default bin offset) from the base read voltage level that is according to the bin assigned to the block 170 and a voltage level.

In some examples, the values of the bin offsets may be preconfigured at the memory system 110. For example, the bin offsets may be collected during a scanning operation performed during a manufacturing process associated with the memory system 110 or during power on, and the bin offsets may fail to reflect a current condition of the memory system 110 (e.g., may be based on outdated information or measurements). Additionally, or alternatively, the bin offsets may be applied uniformly across memory devices 130, without consideration for unit-to-unit charge loss variations which may occur. According to these and other examples, the memory system 110 may perform reads with read voltages that are inaccurate, which may result in errors in memory access and increased latencies.

In accordance with examples described herein, the memory system 110 may perform a dynamic bin offset adjustment procedure, in which the bin offsets at the memory system 110 may be according to performance metrics obtained based on (e.g., in response to) one or more read operations. That is, the memory system may perform relatively fine-tuned adjustments to each bin offset to increase or decrease the bin offsets over multiple repetitions or over a life cycle of the memory system. The memory system 110 may identify performance metrics to determine whether such fine-tuned adjustments increase read performance and may apply the fine-tuned adjustments to the bin offset values stored at the memory system 110 accordingly, which may result in increased read performance and reduced latency for memory access.

The system 100 may include any quantity of non-transitory computer readable media that support dynamic adjustment of bin offsets. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

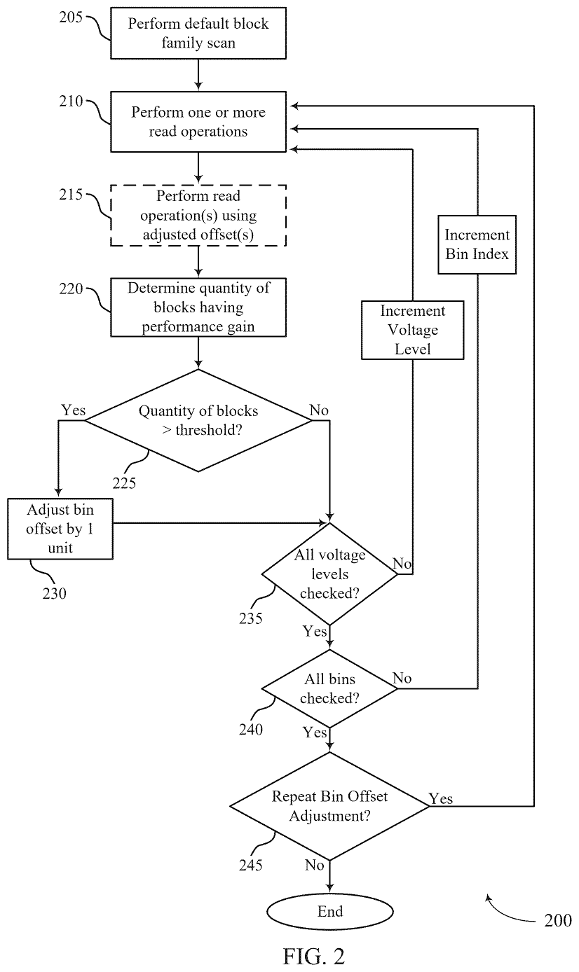

FIG. 2 shows an example of a process 200 that supports dynamic adjustment of bin offsets in accordance with examples as disclosed herein. The process 200 may implement aspects or operations of a system, which may be an example of a system 100, as described with reference to FIG. 1. For example, the process 200 may be implemented by a memory system, which may be an example of a memory system 110. In some cases, the process 200 may be facilitated by a memory system controller, which may be an example of a memory system controller 115.

In the following description of the process 200, the methods, techniques, processes, and operations may be performed in different orders or at different times. Further, some operations may be left out of the process 200, or other operations may be added to the process 200. Aspects of the process 200 may be implemented by one or more controllers, among other components. Additionally, or alternatively, aspects of the process 200 may be implemented as instructions stored in one or more memories (e.g., volatile memory, non-volatile memory). For example, the instructions, when executed by one or more controllers (e.g., the memory system controller 115, local controller 135), may cause the one or more controllers (or a device or a system) to perform the operations of the process 200.

The memory system may include one or more memory system controllers (e.g., NAND controllers) configured to facilitate operations of the memory system. The memory system may also include one or more memory devices (e.g., NAND devices), which may each include one or more memory arrays (e.g., NAND arrays) and one or more local controllers. The one or more memory arrays may each include a quantity of blocks, where each block may include a quantity of memory cells (e.g., NAND cells) each configured to store one or more bits of information for the memory system. For example, during write operations (e.g., programming operations), the memory system may store different logic values in the memory cells by setting the threshold voltages of the memory cells to different target voltage levels associated with the logic values. To read the logic values, the memory cells may be accessed based on applying a voltage to the memory cells and monitoring whether current flows from the memory cell. For example, a memory cell may be read based on applying a read voltage corresponding to the target voltage level applied during the write operation to the memory cell and monitoring a current flowing from the memory cell to determine its logic state.

In some examples, memory cells of the memory system may experience charge loss over time, due to temperature fluctuation or both, where the charge loss may affect the voltage levels stored by the memory cells, thereby affecting read operations (e.g., if the voltage level of the memory cell shifts, a base read voltage may not trigger current to flow from the memory cell). Accordingly, to account for such charge loss, the memory system may assign each block of a memory system to a respective bin of a set of bins. For example, each bin may define a grouping of blocks that have a substantially similar elapsed time since programming (e.g., are programmed at or around the same time), thereby having substantially similar charge loss. With reference to Table 1, the memory system maintain several bins (e.g., bin offsets 0 through 7), where each bin have a set of bin offset values (L1_n through L7_n).

TABLE 1
Bin offset values for TLC reference voltages

| | Bin 0 | Bin 1 | Bin 2 | Bin 3 | Bin 4 | Bin 5 | Bin 6 | Bin 7 |
|---|---|---|---|---|---|---|---|---|
| Reference | offset | offset | offset | offset | offset | offset | offset | offset |
| voltage | value | value | value | value | value | value | value | value |
| L1 | L1_0 | L1_1 | L1_2 | L1_3 | L1_4 | L1_5 | L1_6 | L1_7 |
| L2 | L2_0 | L2_1 | L2_2 | L2_3 | L2_4 | L2_5 | L2_6 | L2_7 |
| L3 | L3_0 | L3_1 | L3_2 | L3_3 | L3_4 | L3_5 | L3_6 | L3_7 |
| L4 | L4_0 | L4_1 | L4_2 | L4_3 | L4_4 | L4_5 | L4_6 | L4_7 |
| L5 | L5_0 | L5_1 | L5_2 | L5_3 | L5_4 | L5_5 | L5_6 | L5_7 |
| L6 | L6_0 | L6_1 | L6_2 | L6_3 | L6_4 | L6_5 | L6_6 | L6_7 |
| L7 | L7_0 | L7_1 | L7_2 | L7_3 | L7_4 | L7_5 | L7_6 | L7_7 |

As illustrated in Table 1, each respective bin offset may be associated with a respective reference voltage level, where such reference voltage levels may be utilized by the memory system to read memory cells of blocks of memory cells. For example, each reference voltage may have a corresponding set of bin offsets (denoted Ln_0 through Ln_7 for reference voltage n) for adjusting the reference voltage so that the memory system can compensate for charge loss. So, the set of bin offsets for a reference voltage may include an offset value for different amounts or ranges of charge loss, which are referred to herein as “bins,” (e.g., bin 0 through bin 7). The bin offsets for a bin may vary across reference voltages because higher threshold voltages may be associated with more severe charge loss.

In some cases, the memory system may perform read operations by applying one or more read voltages to blocks of memory cells to be read. Each of the read voltages used may be based on a reference voltage level (e.g., a standard read voltage) and a bin offset (e.g., a default bin offset) from the base read voltage level that is based on a bin (e.g., according to a charge loss stage) of the block to be read and a voltage level, according to Table 1.

In some cases, however, the values of the bin offsets in Table 1 may be preconfigured at the memory system. For example, the bin offsets may be collected during a scanning operation performed during a manufacturing process associated with the memory system or during power on, and the bin offsets may fail to reflect a current condition of the memory system (e.g., may be based on outdated information or measurements). Additionally, or alternatively, the bin offsets may be applied uniformly across memory devices, without consideration for unit-to-unit charge loss variations which may occur. According to these and other examples, the memory system may perform reads with read voltages that are inaccurate (due to the preconfigured or static bin offsets), which may result in errors in memory access and increased latencies.

In accordance with examples described herein, the process 200 may be an example of a dynamic bin offset adjustment procedure, in which the bin offsets may be adjusted based on (e.g., according to) performance metrics obtained in response to (e.g., according to) one or more operations. That is, the memory system (e.g., a memory system controller 115) may make relatively fine-tuned adjustments (e.g., increments or decrements) to each bin offset over multiple repetitions or over a life cycle of the memory system, which may result in increased read performance and reduced latency for memory access.

For example, at 205, a scan operation (e.g., a default block family, a default BFEA scan) may be performed. That is, the memory system (e.g., a memory system controller 115) may perform the scan operation to track charge loss of memory cells across multiple blocks of the memory system and assign each block to a respective bin of a set of bins according to the measured charge loss. As described herein, each bin may define a grouping of blocks that have a substantially similar elapsed time since programming (e.g., are programmed at or around the same time). Accordingly, each block within a bin may have a similar amount of charge loss, where an amount of charge loss of a block may be a function of the elapsed time from a programming operation, a temperature fluctuation of the memory system, or both. As described herein with reference to table 1, each bin may be associated with multiple bin offsets, where each bin offset may be associated with a respective voltage level that may be programmed into a memory cell.

As an illustrative example of the scan procedure, the memory system (e.g., the memory system controller) may program a first block at time 0 and assign the first block to the first bin (e.g., bin 1). Accordingly, in a subsequent scan operation (e.g., periodically performed), the memory system may determine whether the bin offsets for the first block, and thus the bin assignment, should be updated to better track voltage distribution shift over time (e.g., update for charge loss). For example, during the scan operation, the memory system controller may determine that the bin offsets for the first block should be updated to the bin offsets assigned to a second bin (e.g., bin 2), for example, according to an elapsed time from programming, an amount of charge loss experienced at the memory cells of the block, and/or a voltage distribution shift experienced at the memory cells of the block, among other examples. As such, the memory system controller may reassign the first block to the second bin. The memory system may perform such operations for each block assigned to a bin, thereby either maintaining or adjusting the bin assignments for each block of the memory system.

At 210, one or more read operations may be performed. For example, in response to, or as part of, performing the scan operation at 205, the memory system (e.g., via the memory system controller) may perform one or more read operations on a first set of blocks assigned to a first bin to determine an adjustment for a first bin offset of the first bin, where the first bin offset corresponds to a first voltage level.

In some examples, as part of the one or more read operations, the memory system (e.g., a memory system controller) may perform a first read operation on the first set of blocks using a first read voltage, where the first read voltage is based on (e.g., adjusted according to) a first offset (e.g., positive offset). Similarly, the memory system may perform a second read operation on the first set of blocks using a second read voltage, where the second read voltage is based on (e.g., adjusted according to) the second offset (e.g., negative offset). In such examples, the first offset may be greater than the first bin offset, while the second offset may be less than the first bin offset. In some examples, the first offset and the second offset may be offset from the first bin offset by a same amount, but the first offset being offset positively from the first bin offset and the second offset being offset negatively from the second bin offset.

In some other examples, the memory system (e.g., a memory system controller 115) may perform a read calibration procedure to obtain (e.g., determine, calculate, identify) an adjusted offset associated with the first bin offset. For example, the memory system may perform the one or more read operations on the first set of blocks to determine a shift in the first voltage level (e.g., target voltage level, reference voltage level) for the first set of blocks. Accordingly, the memory system may obtain the adjusted offset based on (e.g., according to) the determined shift obtained in response to the read calibration procedure.

In some examples, the read calibration procedure may include determining a midpoint between the first voltage level and an adjacent voltage level or checking a location of a valley between the first voltage level and an adjacent voltage level. For example, the memory system may determine where a valley is located between two adjacent voltage levels based on (e.g., according to) performing the one or more read operations, and may determine how much the valley has shifted (e.g., in millivolts). If the memory system determines (e.g., based on the read calibration procedure) that one or more of the target voltage levels have shifted for the first set of blocks, the adjusted offset obtained from the read calibration procedure may differ from the first bin offset. In some examples, the read calibration procedure may include an automatic read calibration (ARC) procedure.

At 215, a read operation on the first set of blocks may be performed according to the adjusted offset identified at 210. For example, if, at 210, the memory system obtains the adjusted offset according to the read calibration procedure, then the memory system (e.g., a memory system controller 115) may perform a second read operation of the one or more read operations using a read voltage level that is based on (e.g., adjusted according to) the adjusted offset obtained from the read calibration procedure.

At 220, a quantity of blocks from the first set of blocks may be determined in response to performing the one or more read operations at 210 and 215. For example, the memory system (e.g., a memory system controller 115) may determine a quantity of blocks from the first set of blocks of the first bin that have a performance metric satisfying a threshold performance as a result of the one or more read operations. For example, based on performing the one or more read operations, the memory system (e.g., a memory system controller 115) may calculate a bit error rate (BER) (e.g., performance metric) for each block of the first set of blocks of the first bin. Accordingly, the memory system may determine a quantity of blocks from the first set of blocks that have BER that satisfies a BER threshold.

In some examples, if, at 210, the memory system performs read operations using both the first offset (e.g., positive offset) and the second offset (e.g., negative offset), the memory system may calculate a first BER for each block of the first set of blocks in response to the first read operation (using the first offset) and calculate a second BER for each block of the second set of blocks in response to the second read operation (using the second offset). Accordingly, the memory system may determine a first quantity of blocks from the first set of blocks that have a first BER that satisfies the BER threshold and determine a second quantity of blocks of the first set of blocks that have a second BER that satisfies the BER threshold.

In some examples, if, at 215, the memory system performs the second read operation that is according to the adjusted offset, the memory system may calculate a BER for each block of the first set of blocks in response to the second read operation (using the adjusted offset). Accordingly, the memory system may determine a quantity of blocks from the first set of blocks that have a BER that satisfies the BER threshold.

At 225, it may be determined whether the quantity of blocks, determined at 220, satisfies a threshold quantity. For example, the memory system (e.g., a memory system controller 115) may determine whether the quantity of blocks satisfies a threshold quantity. In some examples, the memory system may determine whether the quantity of blocks satisfying the performance threshold satisfies a threshold percentage (e.g., a majority percentage, such as 50%, 70%) of the first set of blocks. For example, if, at 225, the quantity of blocks satisfies the threshold quantity, the first bin offset may be adjusted.

In some examples, if, at 220, the memory system determines the first quantity of blocks satisfying the performance threshold responsive to the first read operation (e.g., by reading the blocks according to the positive offset) and the second quantity of blocks satisfying the performance threshold responsive to the second read operation (e.g., by reading the blocks according to the negative offset), the memory system may compare both the first quantity of blocks and the second quantity of blocks to the threshold. If the first quantity of blocks satisfies the threshold, the memory system may increment the first bin offset for the first voltage level. If the second quantity of blocks satisfies the threshold, the memory system may decrement the first bin offset for the first voltage level.

In some other examples, if the adjusted offset (e.g., obtained at 215) is greater than the first bin offset and the quantity of blocks (e.g., obtained at 220) is greater than the threshold, then, at 230, the memory system may increment the first bin offset for the first voltage level. Alternatively, if the adjusted offset (e.g., obtained at 215) is less than the first bin offset and the quantity of blocks (e.g., obtained at 220) is greater than the threshold quantity, the memory system may decrement the first bin offset for the first voltage level.

In such examples, the memory system may adjust (e.g., increment or decrement) the first bin offset by one unit according to a digital-to-analog (DAC) conversion associated with the memory system. For example, the bin offset may be fine-tuned with a smallest available adjustment to the bin offset voltage value according to a DAC capability of the memory system. Additionally, the total first bin offset may not exceed a threshold bin offset, such that if the first bin offset is equal to the threshold bin offset, the memory system may refrain from incrementing the first bin offset. In some examples, if the quantity of blocks determined at 220 does not satisfy the performance threshold, the memory system may refrain from adjusting the first bin offset, and, instead, maintain the value of the first bin offset.

After the bin offset adjustment procedure has been performed on the first bin offset for the first voltage level, corresponding to the first bin offset of the first bin, according to steps 210 through 230, at 235 it may be determined whether additional voltage levels associated with the first bin are to be checked. The memory system (e.g., a memory system controller 115) may loop through steps 210 through 230 for a remainder of the voltage levels (e.g., target voltage levels) configured for the memory system (e.g., sixteen voltage levels for QLC, eight voltage levels for TLC, four voltage levels for MLC, etc.), such that each bin offset of the first bin might be adjusted accordingly. At 240, it may be determined whether additional bins are to be checked. The memory system (e.g., a memory system controller 115) may loop through steps 210 through 240 for a remainder of the bins (e.g., eight bins) configured for blocks of the memory system.

At 245, it may be determined whether the bin offset adjustment procedure for adjusting bin offsets at the memory system is to be repeated. For example, the memory system (e.g., a memory system controller 115) may loop through steps 210 through 240 for some quantity of N repetitions (e.g., allowing for each of the default bin offsets to be offset by more than one unit, for increased fine tuning of the bin offsets). The value N may be preconfigured at the memory system or may be indicated by a host system (e.g., a host system 105). Additionally, or alternatively, the memory system may loop through steps 210 through 240 periodically. For example, the memory system may perform the bin offset adjustment procedure defined herein with respect to steps 210 through 240 according to a periodicity, during a charge loss stage, during one or more error correction operations (e.g., error correction stages), or a combination thereof.

Thus, according to the process 200 among other examples, the memory system may perform a dynamic bin offset adjustment procedure to dynamically adjust the bin offsets for each bin and for each voltage level associated with blocks of the memory system. By repeating the steps of the process 200 over multiple repetitions and/or over time, the memory system may fine-tune the bin offsets such that the bin offsets reflect a current condition of the read voltages at blocks of the memory system, resulting in more accurate reads without errors (e.g., a reduced BEC) and reduced latencies as a result of reduced error correction operations at the memory system. In examples where slow charge loss varies over time or across units, the dynamic bin offset adjustment may provide for accurate read voltages that are dynamically tuned to account for such variations.

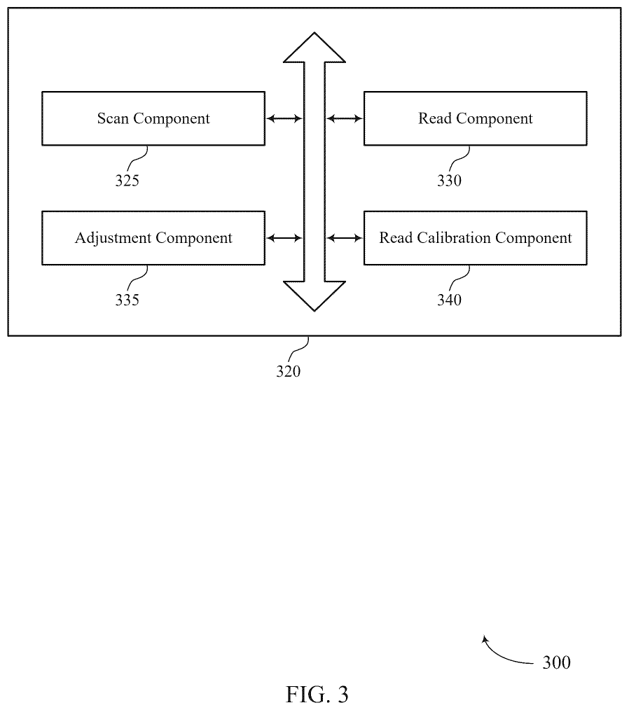

FIG. 3 shows a block diagram 300 of a memory system 320 that supports dynamic adjustment of bin offsets in accordance with examples as disclosed herein. The memory system 320 may be an example of aspects of a memory system as described with reference to FIGS. 1 through 2. The memory system 320, or various components thereof, may be an example of means for performing various aspects of dynamic adjustment of bin offsets as described herein. For example, the memory system 320 may include a scan component 325, a read component 330, an adjustment component 335, a read calibration component 340, or any combination thereof. Each of these components, or components of subcomponents thereof (e.g., one or more processors, one or more memories), may communicate, directly or indirectly, with one another (e.g., via one or more buses).

The scan component 325 may be configured as or otherwise support a means for performing a scan operation on a plurality of blocks to assign each block of the plurality of blocks to a bin of a set of bins, where each bin of the set of bins is associated with a set of bin offsets, and where each bin offset of a respective set of bin offsets is associated with a voltage level. The read component 330 may be configured as or otherwise support a means for performing, in response to performing the scan operation, one or more read operations on a set of blocks associated with a first bin of the set of bins. The adjustment component 335 may be configured as or otherwise support a means for adjusting a first bin offset associated with a first voltage level according to a quantity of blocks from the set of blocks having a respective performance metric that satisfies a performance threshold in response to the one or more read operations.

In some examples, to support performing the one or more read operations, the read component 330 may be configured as or otherwise support a means for performing a first read operation of the one or more read operations using a first read voltage that is in accordance with a first offset. In some examples, to support performing the one or more read operations, the read component 330 may be configured as or otherwise support a means for performing a second read operation of the one or more read operations using a second read voltage that is in accordance with a second offset, where adjusting the first bin offset is in accordance with the quantity of blocks having the respective performance metric that satisfies the performance threshold in response to the first read operation or the second read operation.

In some examples, to support adjusting the first bin offset, the adjustment component 335 may be configured as or otherwise support a means for incrementing the first bin offset in accordance with the quantity of blocks satisfying a threshold, where each of the quantity of blocks have the respective performance metric that satisfies the performance threshold in response to the first read operation.

In some examples, to support adjusting the first bin offset, the adjustment component 335 may be configured as or otherwise support a means for decrementing the first bin offset in accordance with the quantity of blocks satisfying a threshold, where each of the quantity of blocks have the respective performance metric that satisfies the performance threshold in response to the second read operation.

In some examples, the first offset is greater than the first bin offset. In some examples, the second offset is less than the first bin offset.

In some examples, the first offset is a positive offset. In some examples, the second offset is a negative offset.

In some examples, the read calibration component 340 may be configured as or otherwise support a means for obtaining, as part of a read calibration procedure, an adjusted offset associated with the first voltage level in accordance with performing at least a first read operation of the one or more read operations. In some examples, the read component 330 may be configured as or otherwise support a means for performing a second read operation of the one or more read operations using a read voltage that is in accordance with the adjusted offset, where adjusting the first bin offset is in accordance with the quantity of blocks having the respective performance metric that satisfies the performance threshold in response to the second read operation.

In some examples, to support adjusting the first bin offset, the adjustment component 335 may be configured as or otherwise support a means for incrementing the first bin offset in accordance with the quantity of blocks satisfying a threshold, where each of the quantity of blocks have the respective performance metric that satisfies the performance threshold in accordance with the adjusted offset being a positive offset.

In some examples, to support adjusting the first bin offset, the adjustment component 335 may be configured as or otherwise support a means for decrementing the first bin offset in accordance with the quantity of blocks satisfying a threshold, where each of the quantity of blocks have the respective performance metric that satisfies the performance threshold in accordance with the adjusted offset being a negative offset.

In some examples, the read component 330 may be configured as or otherwise support a means for performing, in response to performing the scan operation, one or more second read operations on the set of blocks. In some examples, the adjustment component 335 may be configured as or otherwise support a means for adjusting a second bin offset according to a second quantity of blocks from the set of blocks having a respective second performance metric that satisfies the performance threshold in response to the one or more read operations, where the second bin offset is associated with a second voltage level and is associated with the first bin.

In some examples, to support performing the one or more second read operations, the read component 330 may be configured as or otherwise support a means for performing a first read operation of the one or more second read operations using a first read voltage that is in accordance with the second bin offset and a first offset. In some examples, to support performing the one or more second read operations, the read component 330 may be configured as or otherwise support a means for performing a second read operation of the one or more second read operations using a second read voltage that is in accordance with the second bin offset and a second offset, where adjusting the second bin offset is in accordance with the second quantity of blocks having the respective second performance metric that satisfies the performance threshold in response to the first read operation or the second read operation.

In some examples, to support adjusting the second bin offset, the adjustment component 335 may be configured as or otherwise support a means for incrementing the second bin offset in accordance with the second quantity of blocks satisfying a threshold, where each of the second quantity of blocks have the respective second performance metric that satisfies the performance threshold in response to the first read operation. In some examples, to support adjusting the second bin offset, the adjustment component 335 may be configured as or otherwise support a means for decrementing the second bin offset in accordance with the second quantity of blocks satisfying the threshold, where each of the second quantity of blocks have the respective second performance metric that satisfies the performance threshold in response to the second read operation.

In some examples, the read calibration component 340 may be configured as or otherwise support a means for obtaining, as part of a read calibration procedure, an adjusted offset associated with the second voltage level in accordance with performing at least a first read operation of the one or more second read operations. In some examples, the read component 330 may be configured as or otherwise support a means for performing a second read operation of the one or more second read operations using a read voltage that is in accordance with the adjusted offset, where adjusting the second bin offset is in accordance with the second quantity of blocks having the respective second performance metric that satisfies the performance threshold in response to the second read operation.

In some examples, to support adjusting the second bin offset, the adjustment component 335 may be configured as or otherwise support a means for incrementing the second bin offset in accordance with the second quantity of blocks satisfying a threshold, where each of the second quantity of blocks have the respective second performance metric that satisfies the performance threshold in accordance with the adjusted offset being a positive offset. In some examples, to support adjusting the second bin offset, the adjustment component 335 may be configured as or otherwise support a means for decrementing the second bin offset in accordance with the second quantity of blocks satisfying a threshold, where each of the second quantity of blocks have the respective second performance metric that satisfies the performance threshold in accordance with the adjusted offset being a negative offset.

In some examples, the read component 330 may be configured as or otherwise support a means for performing, in response to performing the scan operation, one or more second read operations on a second set of blocks associated with a second bin of the set of bins. In some examples, the adjustment component 335 may be configured as or otherwise support a means for adjusting a second bin offset according to a second quantity of blocks from the second set of blocks having a respective second performance metric that satisfies the performance threshold in response to the one or more read operations, where the second bin offset is associated with the first voltage level and associated with the second bin.

In some examples, to support performing the one or more second read operations, the read component 330 may be configured as or otherwise support a means for performing a first read operation of the one or more second read operations using a first read voltage that is in accordance with the second bin offset and a first offset. In some examples, to support performing the one or more second read operations, the read component 330 may be configured as or otherwise support a means for performing a second read operation of the one or more second read operations using a second read voltage that is in accordance with the second bin offset and a second offset, where adjusting the second bin offset is in accordance with the second quantity of blocks having the respective second performance metric that satisfies the performance threshold in response to the first read operation or the second read operation.

In some examples, to support adjusting the second bin offset, the adjustment component 335 may be configured as or otherwise support a means for incrementing the second bin offset in accordance with the second quantity of blocks satisfying a threshold, where each of the second quantity of blocks have the respective second performance metric that satisfies the performance threshold in response to the first read operation. In some examples, to support adjusting the second bin offset, the adjustment component 335 may be configured as or otherwise support a means for decrementing the second bin offset in accordance with the second quantity of blocks satisfying the threshold, where each of the second quantity of blocks have the respective second performance metric that satisfies the performance threshold in response to the second read operation.

In some examples, the read calibration component 340 may be configured as or otherwise support a means for obtaining, as part of a read calibration procedure, an adjusted offset associated with the first voltage level in accordance with performing at least a first read operation of the one or more second read operations. In some examples, the read component 330 may be configured as or otherwise support a means for performing a second read operation of the one or more second read operations using a read voltage that is in accordance with the adjusted offset, where adjusting the second bin offset is in accordance with the second quantity of blocks having the respective second performance metric that satisfies the performance threshold in response to the second read operation.

In some examples, to support adjusting the second bin offset, the adjustment component 335 may be configured as or otherwise support a means for incrementing the second bin offset in accordance with the second quantity of blocks satisfying a threshold, where each of the second quantity of blocks have the respective second performance metric that satisfies the performance threshold in accordance with the adjusted offset being a positive offset. In some examples, to support adjusting the second bin offset, the adjustment component 335 may be configured as or otherwise support a means for decrementing the second bin offset in accordance with the second quantity of blocks satisfying a threshold, where each of the second quantity of blocks have the respective second performance metric that satisfies the performance threshold in accordance with the adjusted offset being a negative offset.

In some examples, the respective performance metric includes a bit error rate. In some examples, the performance threshold is a bit error rate threshold.

In some examples, the one or more read operations are performed according to a first periodicity, performed during a charge loss stage, or performed during error correction operations, or any combination thereof.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

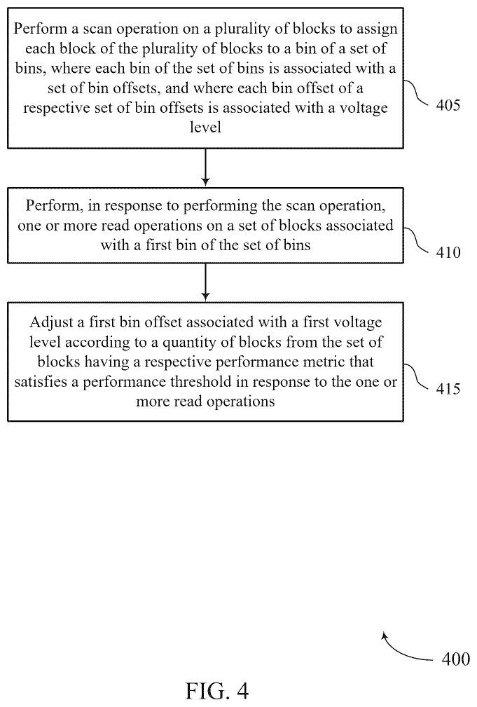

FIG. 4 shows a flowchart illustrating a process 400 that supports dynamic adjustment of bin offsets in accordance with examples as disclosed herein. The operations of process 400 may be implemented by a memory system or its components as described herein. For example, the operations of process 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the process may include performing a scan operation on a plurality of blocks to assign each block of the plurality of blocks to a bin of a set of bins, where each bin of the set of bins is associated with a set of bin offsets, and where each bin offset of a respective set of bin offsets is associated with a voltage level. In some examples, aspects of the operations of 405 may be performed by a scan component 325 as described with reference to FIG. 3.

At 410, the process may include performing, in response to performing the scan operation, one or more read operations on a set of blocks associated with a first bin of the set of bins. In some examples, aspects of the operations of 410 may be performed by a read component 330 as described with reference to FIG. 3.

At 415, the process may include adjusting a first bin offset associated with a first voltage level according to a quantity of blocks from the set of blocks having a respective performance metric that satisfies a performance threshold in response to the one or more read operations. In some examples, aspects of the operations of 415 may be performed by an adjustment component 335 as described with reference to FIG. 3.

In some examples, an apparatus as described herein may perform a process or processes, such as the process 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for performing a scan operation on a plurality of blocks to assign each block of the plurality of blocks to a bin of a set of bins, where each bin of the set of bins is associated with a set of bin offsets, and where each bin offset of a respective set of bin offsets is associated with a voltage level; performing, in response to performing the scan operation, one or more read operations on a set of blocks associated with a first bin of the set of bins; and adjusting a first bin offset associated with a first voltage level according to a quantity of blocks from the set of blocks having a respective performance metric that satisfies a performance threshold in response to the one or more read operations.

Aspect 2: The method, apparatus, or non-transitory computer-readable medium of aspect 1, where performing the one or more read operations includes operations, features, circuitry, logic, means, or instructions, or any combination thereof for performing a first read operation of the one or more read operations using a first read voltage that is in accordance with a first offset and performing a second read operation of the one or more read operations using a second read voltage that is in accordance with a second offset, where adjusting the first bin offset is in accordance with the quantity of blocks having the respective performance metric that satisfies the performance threshold in response to the first read operation or the second read operation.

Aspect 3: The method, apparatus, or non-transitory computer-readable medium of aspect 2, where adjusting the first bin offset includes operations, features, circuitry, logic, means, or instructions, or any combination thereof for incrementing the first bin offset in accordance with the quantity of blocks satisfying a threshold, where each of the quantity of blocks have the respective performance metric that satisfies the performance threshold in response to the first read operation.

Aspect 4: The method, apparatus, or non-transitory computer-readable medium of any of aspects 2 through 3, where adjusting the first bin offset includes operations, features, circuitry, logic, means, or instructions, or any combination thereof for decrementing the first bin offset in accordance with the quantity of blocks satisfying a threshold, where each of the quantity of blocks have the respective performance metric that satisfies the performance threshold in response to the second read operation.

Aspect 5: The method, apparatus, or non-transitory computer-readable medium of any of aspects 2 through 4, where the first offset is greater than the first bin offset and the second offset is less than the first bin offset.

Aspect 6: The method, apparatus, or non-transitory computer-readable medium of any of aspects 2 through 5, where the first offset is a positive offset and the second offset is a negative offset.

Aspect 7: The method, apparatus, or non-transitory computer-readable medium of any of aspects 1 through 6, further including operations, features, circuitry, logic, means, or instructions, or any combination thereof for obtaining, as part of a read calibration procedure, an adjusted offset associated with the first voltage level in accordance with performing at least a first read operation of the one or more read operations and performing a second read operation of the one or more read operations using a read voltage that is in accordance with the adjusted offset, where adjusting the first bin offset is in accordance with the quantity of blocks having the respective performance metric that satisfies the performance threshold in response to the second read operation.

Aspect 8: The method, apparatus, or non-transitory computer-readable medium of aspect 7, where adjusting the first bin offset includes operations, features, circuitry, logic, means, or instructions, or any combination thereof for incrementing the first bin offset in accordance with the quantity of blocks satisfying a threshold, where each of the quantity of blocks have the respective performance metric that satisfies the performance threshold in accordance with the adjusted offset being a positive offset.

Aspect 9: The method, apparatus, or non-transitory computer-readable medium of any of aspects 7 through 8, where adjusting the first bin offset includes operations, features, circuitry, logic, means, or instructions, or any combination thereof for decrementing the first bin offset in accordance with the quantity of blocks satisfying a threshold, where each of the quantity of blocks have the respective performance metric that satisfies the performance threshold in accordance with the adjusted offset being a negative offset.

Aspect 10: The method, apparatus, or non-transitory computer-readable medium of any of aspects 1 through 9, further including operations, features, circuitry, logic, means, or instructions, or any combination thereof for performing, in response to performing the scan operation, one or more second read operations on the set of blocks and adjusting a second bin offset according to a second quantity of blocks from the set of blocks having a respective second performance metric that satisfies the performance threshold in response to the one or more read operations, where the second bin offset is associated with a second voltage level and is associated with the first bin.

Aspect 11: The method, apparatus, or non-transitory computer-readable medium of aspect 10, where performing the one or more second read operations includes operations, features, circuitry, logic, means, or instructions, or any combination thereof for performing a first read operation of the one or more second read operations using a first read voltage that is in accordance with the second bin offset and a first offset and performing a second read operation of the one or more second read operations using a second read voltage that is in accordance with the second bin offset and a second offset, where adjusting the second bin offset is in accordance with the second quantity of blocks having the respective second performance metric that satisfies the performance threshold in response to the first read operation or the second read operation.

Aspect 12: The method, apparatus, or non-transitory computer-readable medium of aspect 11, where adjusting the second bin offset includes operations, features, circuitry, logic, means, or instructions, or any combination thereof for incrementing the second bin offset in accordance with the second quantity of blocks satisfying a threshold, where each of the second quantity of blocks have the respective second performance metric that satisfies the performance threshold in response to the first read operation and decrementing the second bin offset in accordance with the second quantity of blocks satisfying the threshold, where each of the second quantity of blocks have the respective second performance metric that satisfies the performance threshold in response to the second read operation.

Aspect 13: The method, apparatus, or non-transitory computer-readable medium of any of aspects 10 through 12, further including operations, features, circuitry, logic, means, or instructions, or any combination thereof for obtaining, as part of a read calibration procedure, an adjusted offset associated with the second voltage level in accordance with performing at least a first read operation of the one or more second read operations and performing a second read operation of the one or more second read operations using a read voltage that is in accordance with the adjusted offset, where adjusting the second bin offset is in accordance with the second quantity of blocks having the respective second performance metric that satisfies the performance threshold in response to the second read operation.

Aspect 14: The method, apparatus, or non-transitory computer-readable medium of aspect 13, where adjusting the second bin offset includes operations, features, circuitry, logic, means, or instructions, or any combination thereof for incrementing the second bin offset in accordance with the second quantity of blocks satisfying a threshold, where each of the second quantity of blocks have the respective second performance metric that satisfies the performance threshold in accordance with the adjusted offset being a positive offset and decrementing the second bin offset in accordance with the second quantity of blocks satisfying a threshold, where each of the second quantity of blocks have the respective second performance metric that satisfies the performance threshold in accordance with the adjusted offset being a negative offset.

Aspect 15: The method, apparatus, or non-transitory computer-readable medium of any of aspects 1 through 14, further including operations, features, circuitry, logic, means, or instructions, or any combination thereof for performing, in response to performing the scan operation, one or more second read operations on a second set of blocks associated with a second bin of the set of bins and adjusting a second bin offset according to a second quantity of blocks from the second set of blocks having a respective second performance metric that satisfies the performance threshold in response to the one or more read operations, where the second bin offset is associated with the first voltage level and associated with the second bin.

Aspect 16: The method, apparatus, or non-transitory computer-readable medium of aspect 15, where performing the one or more second read operations includes operations, features, circuitry, logic, means, or instructions, or any combination thereof for performing a first read operation of the one or more second read operations using a first read voltage that is in accordance with the second bin offset and a first offset and performing a second read operation of the one or more second read operations using a second read voltage that is in accordance with the second bin offset and a second offset, where adjusting the second bin offset is in accordance with the second quantity of blocks having the respective second performance metric that satisfies the performance threshold in response to the first read operation or the second read operation.

Aspect 17: The method, apparatus, or non-transitory computer-readable medium of aspect 16, where adjusting the second bin offset includes operations, features, circuitry, logic, means, or instructions, or any combination thereof for incrementing the second bin offset in accordance with the second quantity of blocks satisfying a threshold, where each of the second quantity of blocks have the respective second performance metric that satisfies the performance threshold in response to the first read operation and decrementing the second bin offset in accordance with the second quantity of blocks satisfying the threshold, where each of the second quantity of blocks have the respective second performance metric that satisfies the performance threshold in response to the second read operation.

Aspect 18: The method, apparatus, or non-transitory computer-readable medium of any of aspects 15 through 17, further including operations, features, circuitry, logic, means, or instructions, or any combination thereof for obtaining, as part of a read calibration procedure, an adjusted offset associated with the first voltage level in accordance with performing at least a first read operation of the one or more second read operations and performing a second read operation of the one or more second read operations using a read voltage that is in accordance with the adjusted offset, where adjusting the second bin offset is in accordance with the second quantity of blocks having the respective second performance metric that satisfies the performance threshold in response to the third read operation.

Aspect 19: The method, apparatus, or non-transitory computer-readable medium of aspect 18, where adjusting the second bin offset includes operations, features, circuitry, logic, means, or instructions, or any combination thereof for incrementing the second bin offset in accordance with the second quantity of blocks satisfying a threshold, where each of the second quantity of blocks have the respective second performance metric that satisfies the performance threshold in accordance with the adjusted offset being a positive offset and decrementing the second bin offset in accordance with the second quantity of blocks satisfying a threshold, where each of the second quantity of blocks have the respective second performance metric that satisfies the performance threshold in accordance with the adjusted offset being a negative offset.

Aspect 20: The method, apparatus, or non-transitory computer-readable medium of any of aspects 1 through 19, where the respective performance metric includes a bit error rate and the performance threshold is a bit error rate threshold.

Aspect 21: The method, apparatus, or non-transitory computer-readable medium of any of aspects 1 through 20, where the one or more read operations are performed according to a first periodicity, performed during a charge loss stage, or performed during error correction operations, or any combination thereof.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
perform a scan operation on a plurality of blocks to assign each block of the plurality of blocks to a bin of a set of bins, wherein each bin of the set of bins is associated with a set of bin offsets, and wherein each bin offset of a respective set of bin offsets is associated with a voltage level;
perform, in response to performing the scan operation, one or more read operations on a set of blocks associated with a first bin of the set of bins; and
adjust a first bin offset associated with a first voltage level according to a quantity of blocks from the set of blocks having a respective performance metric that satisfies a performance threshold in response to the one or more read operations.

2. The memory system of claim 1, wherein, to perform the one or more read operations, the processing circuitry is configured to cause the memory system to:
perform a first read operation of the one or more read operations using a first read voltage that is in accordance with a first offset; and
perform a second read operation of the one or more read operations using a second read voltage that is in accordance with a second offset, wherein adjusting the first bin offset is in accordance with the quantity of blocks having the respective performance metric that satisfies the performance threshold in response to the first read operation or the second read operation.

3. The memory system of claim 2, wherein, to adjust the first bin offset, the processing circuitry is configured to cause the memory system to:
increment the first bin offset in accordance with the quantity of blocks satisfying a threshold, wherein each of the quantity of blocks have the respective performance metric that satisfies the performance threshold in response to the first read operation.

4. The memory system of claim 2, wherein, to adjust the first bin offset, the processing circuitry is configured to cause the memory system to:
decrement the first bin offset in accordance with the quantity of blocks satisfying a threshold, wherein each of the quantity of blocks have the respective performance metric that satisfies the performance threshold in response to the second read operation.

5. The memory system of claim 2, wherein the first offset is greater than the first bin offset and the second offset is less than the first bin offset.

6. The memory system of claim 2, wherein the first offset is a positive offset and the second offset is a negative offset.

7. The memory system of claim 1, wherein the processing circuitry is further configured to cause the memory system to:
obtain, as part of a read calibration procedure, an adjusted offset associated with the first voltage level in accordance with performing at least a first read operation of the one or more read operations; and
perform a second read operation of the one or more read operations using a read voltage that is in accordance with the adjusted offset, wherein adjusting the first bin offset is in accordance with the quantity of blocks having the respective performance metric that satisfies the performance threshold in response to the second read operation.

8. The memory system of claim 7, wherein, to adjust the first bin offset, the processing circuitry is configured to cause the memory system to:
increment the first bin offset in accordance with the quantity of blocks satisfying a threshold, wherein each of the quantity of blocks have the respective performance metric that satisfies the performance threshold in accordance with the adjusted offset being a positive offset.

9. The memory system of claim 7, wherein, to adjust the first bin offset, the processing circuitry is configured to cause the memory system to:
decrement the first bin offset in accordance with the quantity of blocks satisfying a threshold, wherein each of the quantity of blocks have the respective performance metric that satisfies the performance threshold in accordance with the adjusted offset being a negative offset.

10. The memory system of claim 1, wherein the processing circuitry is further configured to cause the memory system to:
perform, in response to performing the scan operation, one or more second read operations on the set of blocks; and
adjust a second bin offset according to a second quantity of blocks from the set of blocks having a respective second performance metric that satisfies the performance threshold in response to the one or more read operations, wherein the second bin offset is associated with a second voltage level and is associated with the first bin.

11. The memory system of claim 10, wherein, to perform the one or more second read operations, the processing circuitry is configured to cause the memory system to:
perform a first read operation of the one or more second read operations using a first read voltage that is in accordance with the second bin offset and a first offset; and
perform a second read operation of the one or more second read operations using a second read voltage that is in accordance with the second bin offset and a second offset, wherein adjusting the second bin offset is in accordance with the second quantity of blocks having the respective second performance metric that satisfies the performance threshold in response to the first read operation or the second read operation.

12. The memory system of claim 11, wherein, to adjust the second bin offset, the processing circuitry is configured to cause the memory system to:
increment the second bin offset in accordance with the second quantity of blocks satisfying a threshold, wherein each of the second quantity of blocks have the respective second performance metric that satisfies the performance threshold in response to the first read operation; or
decrement the second bin offset in accordance with the second quantity of blocks satisfying the threshold, wherein each of the second quantity of blocks have the respective second performance metric that satisfies the performance threshold in response to the second read operation.

13. The memory system of claim 1, wherein the processing circuitry is further configured to cause the memory system to:
perform, in response to performing the scan operation, one or more second read operations on a second set of blocks associated with a second bin of the set of bins; and
adjust a second bin offset according to a second quantity of blocks from the second set of blocks having a respective second performance metric that satisfies the performance threshold in response to the one or more read operations, wherein the second bin offset is associated with the first voltage level and associated with the second bin.

14. The memory system of claim 13, wherein, to perform the one or more second read operations, the processing circuitry is configured to cause the memory system to:
perform a first read operation of the one or more second read operations using a first read voltage that is in accordance with the second bin offset and a first offset; and
perform a second read operation of the one or more second read operations using a second read voltage that is in accordance with the second bin offset and a second offset, wherein adjusting the second bin offset is in accordance with the second quantity of blocks having the respective second performance metric that satisfies the performance threshold in response to the first read operation or the second read operation.

15. The memory system of claim 14, wherein, to adjust the second bin offset, the processing circuitry is configured to cause the memory system to:
increment the second bin offset in accordance with the second quantity of blocks satisfying a threshold, wherein each of the second quantity of blocks have the respective second performance metric that satisfies the performance threshold in response to the first read operation; or
decrement the second bin offset in accordance with the second quantity of blocks satisfying the threshold, wherein each of the second quantity of blocks have the respective second performance metric that satisfies the performance threshold in response to the second read operation.

16. The memory system of claim 1, wherein the one or more read operations are performed according to a first periodicity, performed during a charge loss stage, or performed during error correction operations, or any combination thereof.

17. A non-transitory computer-readable medium storing code comprising instructions which, when executed by processing circuitry of a memory system, cause the memory system to:
perform a scan operation on a plurality of blocks to assign each block of the plurality of blocks to a bin of a set of bins, wherein each bin of the set of bins is associated with a set of bin offsets, and wherein each bin offset of a respective set of bin offsets is associated with a voltage level;
perform, in response to performing the scan operation, one or more read operations on a set of blocks associated with a first bin of the set of bins; and
adjust a first bin offset associated with a first voltage level according to a quantity of blocks from the set of blocks having a respective performance metric that satisfies a performance threshold in response to the one or more read operations.

18. The non-transitory computer-readable medium of claim 17, wherein the instructions to perform the one or more read operations, when executed by the processing circuitry of the memory system, cause the memory system to:
perform a first read operation of the one or more read operations using a first read voltage that is in accordance with a first offset; and
perform a second read operation of the one or more read operations using a second read voltage that is in accordance with a second offset, wherein adjusting the first bin offset is in accordance with the quantity of blocks having the respective performance metric that satisfies the performance threshold in response to the first read operation or the second read operation.

19. The non-transitory computer-readable medium of claim 18, wherein the instructions to adjust the first bin offset, when executed by the processing circuitry of the memory system, cause the memory system to:
increment the first bin offset in accordance with the quantity of blocks satisfying a threshold, wherein each of the quantity of blocks have the respective performance metric that satisfies the performance threshold in response to the first read operation; or
decrement the first bin offset in accordance with the quantity of blocks satisfying the threshold, wherein each of the quantity of blocks have the respective performance metric that satisfies the performance threshold in response to the second read operation.

20. A method by a memory system, comprising:
performing a scan operation on a plurality of blocks to assign each block of the plurality of blocks to a bin of a set of bins, wherein each bin of the set of bins is associated with a set of bin offsets, and wherein each bin offset of a respective set of bin offsets is associated with a voltage level;
performing, in response to performing the scan operation, one or more read operations on a set of blocks associated with a first bin of the set of bins; and
adjusting a first bin offset associated with a first voltage level according to a quantity of blocks from the set of blocks having a respective performance metric that satisfies a performance threshold in response to the one or more read operations.
